(19) United States
(12) Patent Application Publication
(10) Pub. No.: US 2016/0252552 A1
(43) Pub. Date: Sep. 1, 2016

(54) ANALOG TO INFORMATION CONVERTER

(71) Applicants: Roman RABINOVICH, Petah Tikva (IL); EIM DISTRIBUTION LTD., Petach-Tikva (IL)

(72) Inventors: Roman RABINOVICH, PETACH TIKVA (IL); Boris OKLANDER, NAZARETH ILLIT (IL); Asaf ZVIRAN, GIVATAYIM (IL)

(73) Assignees: E.I.M. DISTRIBUTION LTD., PETACH-TIKVA (IL); Roman RABINOVICH, PETACH-TIKVA (IL)

(21) Appl. No.: 15/027,697

(22) PCT Filed: Oct. 7, 2014
(86) PCT No.: PCT/IL2014/050881

§ 371 Date: Apr. 7, 2016

(30) Foreign Application Priority Data
Oct. 8, 2013 (IL) 228776

(51) Int. Cl. G01R 23/167

(52) U.S. Cl. CPC G01R 23/167

(57) ABSTRACT

A method of identifying a spectrum and extracting features thereof for RF signals in an ultra-wide bandwidth comprising the steps of (a) obtaining said RF signal to be analyzed; (b) high-pass filtering said obtained signal; (c) digitizing said high filtered signal; and (d) analyzing said digitized signal. The method further comprises a step of spectrum compressing (SC) including splitting said high pass filtered signal into two channels and Phase true-time delay modulating (shifting) said signal within one of said channels.

### FIELD OF THE INVENTION

This invention relates to signal processing and more particularly to a method of measuring signal features for RF signals within an ultra-wide frequency band-width.

### BACKGROUND OF THE INVENTION

Spectrum sensing is a topical problem for many civilian and military applications, such as cognitive radio, real-time spectrum analyzer, electronic support measures (ESM) or radar warning receiver (RWR) applications. The main challenge in these fields is the capability to intercept, investigate and derive the features of complex RF signals in a wide frequency band-width. Most of the currently state-of the-art systems utilize down-conversion followed by sampling by analog-to-digital converter (ADC) and digital processing in the temporal and spectral domains. The main limitations arise from the band-width and bit depth of the ADC. The ADC is limited in sampling speed and hence in analysis band-width. These limitations were first described by Nyquist-Shannon sampling theorem. Practically, the abovernentioned problem can be solved by combining multiple subsystems. Each subsystem provides down-conversion, sampling by the ADC and analysis of a separated frequency band. Evident drawbacks of this design are high weight-dimension and cost characteristics. Additionally, a memory storage problem arises, sampling the entire spectrum under the limitations of the Nyquist-Shannon sampling theorem cause an inflation of digital data to be stored and processed. in this situation, however, the information level of the signal is often far lower than the actual bandwidth, which prompt the development of more efficient sampling schemes such as analog-to-information. The current state-of-the-art methods of analog-to-information utilizes under-sampling (sampling in a lower frequency than the Nyquist frequency) with advanced signal processing and heuristics in order to recover the original signal features, these under-sampling methods are inherently noisy and the signal features are not always estimated accurately.

In summary, the known technologies are limited in their capability of simultaneous sampling of the whole spectral band of interest. Thus, there is a long-felt and unmet need to provide an analog--to-information converter capable to quickly recognize continuous and pulse RF signals within broad frequency band. Another need is the capability for filtering and discrimination between transmitters overlapping in time but transmitting at different frequencies.

### SUMMARY OF THE INVENTION

It is hence one object of the invention to disclose a method of spectral identification and feature extraction for RF signals in an ultra-wide bandwidth. The aforesaid method comprises the steps of (a) obtaining said RF signal to be analyzed; (b) high-pass filtering of the obtained signal; (c) digitizing a compressed signal; and (d) analyzing digitized signal.

It is a core purpose of the invention to provide the method further comprising a step of spectrum compressing (SC) further comprising splitting said high pass filtered signal to two channels; Phase true-time delay modulating (shifting) said signal within one of said channels and mixing original and modulated signals.

Another object of the invention is to disclose the step of Phase true-time delay modulating comprising a linear modulation with sub-wavelength increments causes the Doppler frequency shift

$${f}_{d} = \frac{v}{c} \cdot {F}_{c} ,$$

where v is the velocity of the linear range modulation defined by digitally controlled switching circuit, c is the speed of light, f_{d} is the Doppler shift and F_{c} is the carrier frequency.

A further object of the invention is to disclose the step of SC comprising linearly mapping high-frequency spectrum within low frequency spectrum band.

A further object of the invention is to disclose the step of analyzing digitized signal comprises Fast Fourier Transform.

A further object of the invention is to disclose an analog-to information converter of an RF signal. The aforesaid converter comprises: (a) spectrum compression unit; (b) a digitizer of an obtained compressed signal; and (c) a digital signal processing unit.

It is a core purpose of the invention to provide the spectrum compression unit further comprising a splitter configured to split a high pass filtered signal to two channels, phase true-time delay line disposed in one of said channels, a mixing unit configured for mixing signals downstream of said channels and a low-pass filter configured for filtering a mixed signal.

Additional object of the invention is to present an optimized implementation for the Analog-to-Information converter, utilizing linear spectrum compression (LSC) implementation. The linear Analog-to-information implementation further comprises a splitter configured to split a high pass filtered signal to two channels, phase true-time delay disposed in one of said channels and two digitizers (analog-to-digital converters) for the sampling of each RF channel separately.

A further object of the invention is to disclose digital signal processing unit which comprises Fast Fourier Transformation for each separate digitized channel and an algorithmic processing for the cross-detection of original and modulated frequencies and the extraction of accurate spectral and temporal signal features.

Additional object of the invention is to present a method to derive spectrum compression by completely digital design, utilizing digital spectrum compression (DSC). The digital Analog-to-information implementation further comprises a splitter configured to split a high pass filtered signal to two channels, followed by two digitizers (analog-to-digital converters) for the sampling of each RF channel separately and a specific digital Doppler processing unit.

A further object of the invention is to disclose digital signal processing unit which generate accurate Doppler-shift in a fully digitally controlled manner. This digital Doppler generator (DDG) processing is characterized by predetermined sampling rates, a decimation procedure, Fast Fourier Transformation and a predetermined normalization of the frequency spectrum.

A further object of the invention is to disclose the converter configured for at least one application selected from the group consisting of; (a) Ultra wide band-width real-time spectrum, (b) Spectrum sensing and management for cognitive radio, (c) Emitter identification and mapping for ESM systems and (d) Ultra wide band-width RWR systems.

### BRIEF DESCRIPTION OF THE DRAWINGS

In order to understand the invention and to see how it may be implemented in practice, a plurality of embodiments is adapted to now be described, by way of non-limiting example only, with reference to the accompanying drawings, in which

FIG. 1 is a flowchart of a method of identifying a spectrum and extracting spectrum features;

FIG. 2 is a flowchart of an optimized method of linear spectrum compression;

FIG. 3 is a schematic diagram of a linear analog-to-information converter; and

FIG. 4 is a schematic diagram of a digital analog-to-information converter.

### DETAILED DESCRIPTION OF THE INVENTION

The following description is provided, so as to enable any person skilled in the art to make use of said invention and sets forth the best modes contemplated by the inventor of carrying out this invention. Various modifications, however, are adapted to remain apparent to those skilled in the art, since the generic principles of the present invention have been defined specifically to provide a method of analyzing spectral characteristic of an RF signal and an apparatus for implementation thereof.

Concurrently mapping transmitters within the whole RF spectrum from 100 MHz to 18 GHz is at present a very relevant task. A solution of this task is primarily limited by the capability of concurrent spectral sampling.

In accordance with the present invention, the spectral band is compressed such that spectral characteristics and spatial layout of the transmitters are kept intact.

The present invention provides a recognition capability of continuous and burst RF signals at a broad frequency bandwidth. Additionally, an analog-to-information converter of the present invention is able to discriminate time overlapping transmitters with different spectral characteristics.

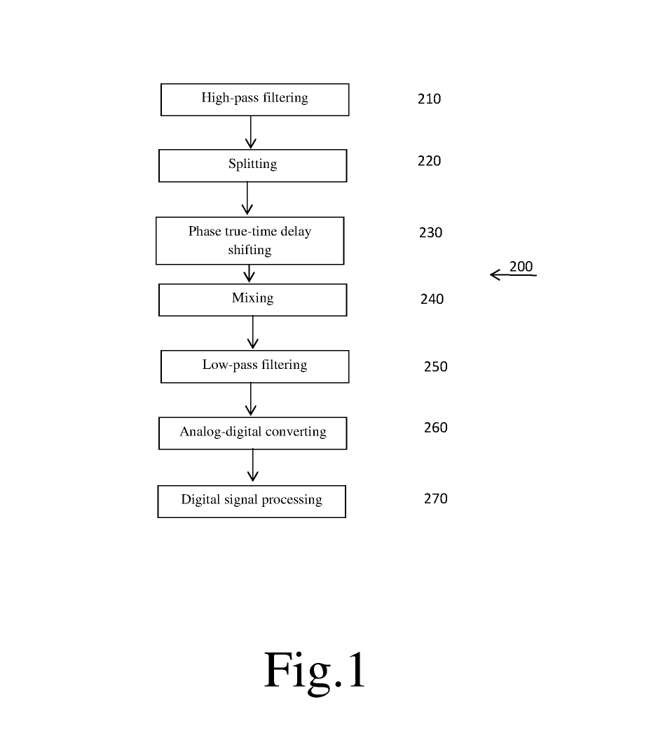

Reference is now made to FIG. 1, presenting a flowchart of a method 200 of identifying a transmitter and extracting spectrum features. In accordance with an exemplar embodiment of the present invention, and obtained signal is high-pass filtered at a step 210. Then, a high-pass filtered signal is split to two channels (step 220). One of the channels is provided with phase true-time delay shifter. Step 230 refers to inserting phase true-time delay to high frequency signal. Original and modulated signals are mixed at a step 240. After that, the obtained mixed signal is low-pass filtered at a step 250 and digitized at a step 260 (analog-digital conversion). An obtained digital signal is processed to identify the transmitter and extract its features at a step 270. In accordance with one embodiment of the present invention, Fast Fourier Transform is used for processing the obtained digital signal.

The present spectrum compression (SC) method can be characterized by the following formulas:

Integration time is given by

$$Int\_time = \frac{{2}^{TTD \_ bit}}{TTD\_switching \_rate} = \frac{1}{Dopp\_res}$$

where

TTD_bit is a number of bits decoding the binary choice of physical delays. The phase true-time delay has 2^{TTD}^{_}^{bit} optional delays.

Dopp_res is Doppler frequency resolution;

TTD_switching_rate is a rate of switching between different values of delays and determines the speed enforced on the signal

Speed indicating a number of switching between different values of delay per time which creates the Doppler frequency is given by

$$V = \frac{TTD\_span}{Int\_time} ,$$

where

TTD_span is the largest range delay that can be chosen in the Phase true-time delay.

Freq_span is the maximal carrier frequency band-width that can be measured and/or compressed by the system, according to Nyquist sampling frequency

$$Freq\_span = \frac{c \cdot Doppler\_span}{V} = \frac{c \cdot {2}^{TTD \_ bit}}{TTD\_span} = \frac{c}{TTD\_Res}$$

where

Dopp_span is the maximal Doppler frequency band-width that can be measured by the system, according to Nyquist sampling frequency; and

c is the light speed.

Freq_res is the minimum carrier Frequency difference between two RF signals that allows discrimination between the signals, or equivalently the resolution of the FFT representation of the carrier frequency.

$$Freq\_res = \frac{c}{TTD\_span} = \frac{c}{Int\_time * V}$$

where

TTD_res is the smallest range delay that can be chosen in the Phase true-time delay, and also the difference between any two consecutive delays (the delay increment of each switching event) during the linear delay modulation.

In order to overcome the limitation of mixer nonlinearity and the limiting relation between TTD_span and the measured Frequency resolution, we further present an optimized linear spectrum compression (LSC) implementation.

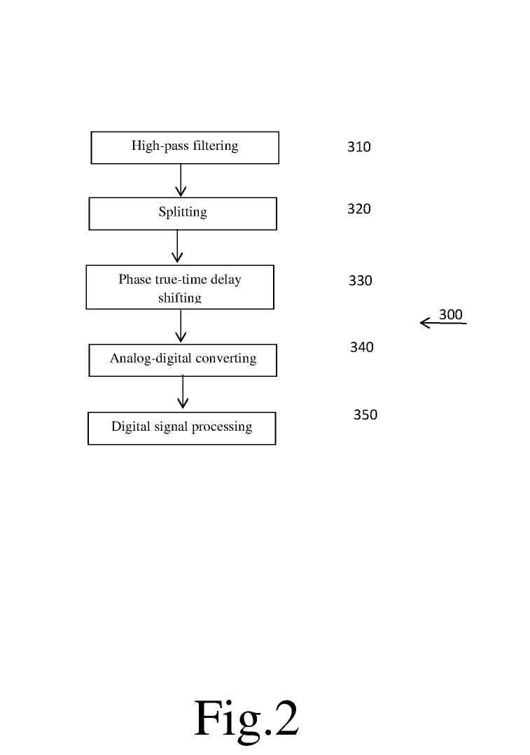

Reference is now made to FIG. 2, presenting a flowchart of an optimized method of linear spectrum compression 300. In accordance with an exemplar embodiment of the present invention, an obtained signal is high-pass filtered at a step 310. Then, a high-pass filtered signal is split to two channels (step 320). One of the channels is provided with phase true-time delay shifter. Step 330 refers to inserting phase true-time delay to high frequency signal. Original and modulated signals are digitized separately at a step 340 (analog-digital conversion). The two obtained digital signals are then processed to identify the transmitter and extract their features at a step 350. In accordance with one embodiment of the present invention, Fast Fourier Transform is used for the processing of the two obtained digital signals, followed by an algorithmic processing for the cross-detection and association of original and modulated frequencies and the extraction of accurate spectral and temporal signal features. It should be noted that the presented implementation supplies two sources of frequency information which can be fused together for the calculation of accurate and ambiguity-free frequency measurement. The first source of frequency information is the Doppler shift between modulated and original frequencies which allows for calculation of ambiguity-free frequency measurement with Mhz scale resolution (according to the Freq_res equation). The second source of frequency information is under-sampled measurement of the original frequency which being combined with the Doppler shift allows for calculation of ambiguity-free frequency measurement with Khz scale resolution.

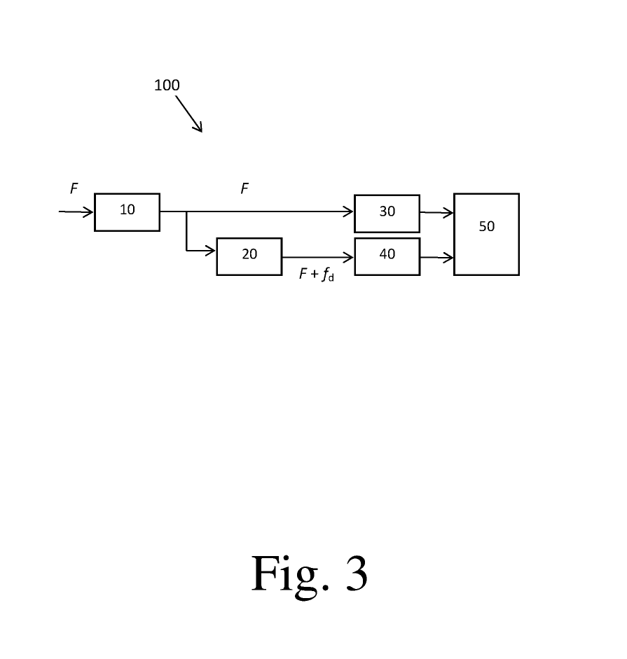

Reference is now made to FIG. 3 presenting a schematic diagram of an analog-to-information converter 100 comprising a high-pass filter 10, a phase true-time delay unit 20, two analog-to-digital converters 30 and 40 and a digital signal processing unit 50.

A signal from a source (antenna or other) is high-pass filtered in the high-pass filter 10. Then, the filtered signal is split into two channels. One of the channels is provided with a phase true-time delay unit 20 which is able to insert a linear delay modulation (interpreted as a Doppler shift) defined as

$${f}_{d} = \frac{v}{c} \cdot {F}_{c} = K \cdot {F}_{c} ,$$

where v is the velocity of the linear range modulation, c is the speed of light, f_{d} is the doppler shift and F_{c} is the carrier frequency.

The variable v is computer-controlled according to a switching rate between different values of physical delay. The aforesaid delay is implemented by means of dynamically controlled switch between RF or optical delay lines. The inserted delay shift is about several mm for each switching event.

Thus, a linear mapping from a carrier frequency (F_{c}) to a low Doppler frequency (f_{d}) is implemented. The parameter K explicitly expresses a compression ratio between the original spectrum (GHz) and a compressed spectrum (MHz) obtained by means of phase true-time delay modulation. It should be emphasized that the aforesaid conversion keeps spectral distances between transmitters, general and internal structures of transmitter waveform.

Signals F_{c} and F_{c}+f_{d} from the two channels are then digitized separately in the analog-to-digital converters 30 and 40, the two digitized signals are analyzed in the digital signal processing unit 50.

Alternatively, the linear spectrum compression (LSC) can be implemented in a completely digital design which renders the phase true-time delay unit (unit 20) unnecessary. For this purpose, we further present a digital spectrum compression (DSC) implementation.

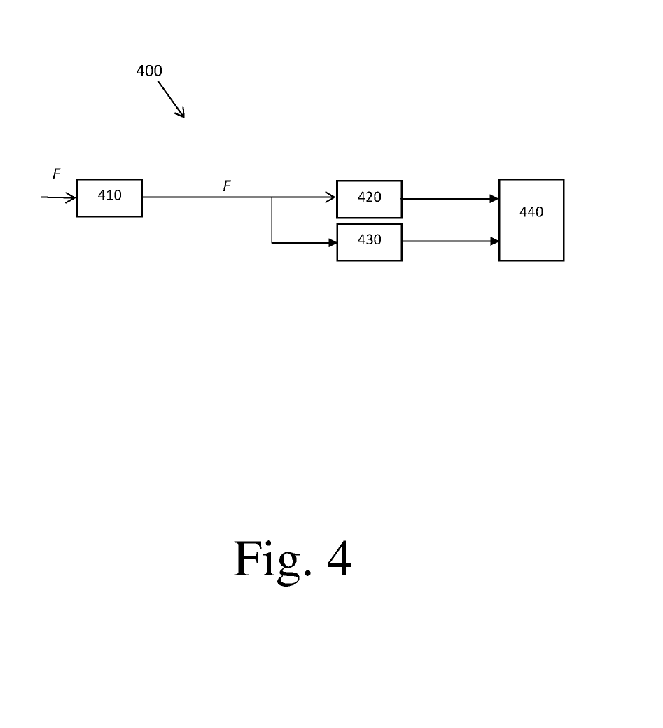

Reference is now made to FIG. 4 presenting a schematic diagram of a digital analog-to-information converter 400 comprising a high-pass filter 410, two analog-to-digital converters 420 and 430 and a digital signal processing unit 440.

A signal from a source (antenna or other) is high-pass filtered in the high-pass filter 410. Then, the filtered signal is split into two channels where the two channels are digitized separately in the analog-to-digital converters 420 and 430. The sampling rate at unit 420 and 430 will be defined as f₁ and f₂, respectively. The relation between the sampling rates at the two analog-to-digital converters is defined as

$${f}_{2} = {f}_{1} \cdot {( 1 + K )}^{- 1} = {f}_{1} \cdot \frac{c}{c + v}$$

where v is the desired Doppler velocity, c is the speed of light, K is the compression ratio, and f₁, f₂ are the sampling rates in unit 420 and 430, respectively.

The two digitized signals generated at unit 420 and 430 will be defined as Y₁ and Y₂, respectively. These digital signals are than analyzed in the digital signal processing unit 440.

A further object of the invention is to disclose the digital signal processing at unit 440 which configured for decimation of Y₁ to equal length as Y₂, Fast Fourier Transform for each separate digitized channel (F(Y₁) and F(Y₂)), and normalization of the frequency spectrum of Y₂ by the following relation: F(Y₂)*(1+K).

We claim that the proposed digital spectrum compression (DSC) implementation is equivalent to the analog Doppler shift method characterized at the linear spectrum compression (LSC). The basis for this claim relies on the mathematical equivalence of the following relations

Define the digitized signal generated from the analog phase true-time delay unit 20 and analog-to-digital converter 40 as W₁, then

$${W}_{1} [ n ] = sin ( 2 π F \cdot [ 1 + K ] \cdot \frac{n}{{f}_{1}} ) = sin ( 2 π F \cdot \frac{n}{{f}_{2}} ) = {Y}_{2} [ n ]$$

where F is input signal frequency, K is the compression ratio, n is the digital sample index, f₁ is the sampling rate at the LSC system implementation and f₂=f₁·(1+K)⁻¹ is the required sampling rate in unit 430 at the DSC implementation. For this sampling rate, the frequency of the under-sampled (aliased) signal generated by Fast Fourier Transform on Y₂ can be represented by

F(Y₂)=F−N·f₂=F−N·f₁·(1+K)⁻¹

where N is the closest replicate of f₂ to F, meaning that N=arg min_{N} (F−N·f₂). Therefore, after normalization of the frequency spectrum by F(Y₂)*(1+K), we get

F(Y₂)·(1+K)=F·(1+K)−N·f₁=F(W₁)

Meaning that there is equivalency between the spectrum mapping generated by the analog phase true-time delay unit 20 and analog-to-digital converter 40 defined as F(W₁) and between the spectrum mapping generated by sampling at rate f₂ at unit 430 and executing the suggested digital processing on Y₂.

Various applications such as Ultra wide band-width real-time spectrum, Spectrum sensing and management for cognitive radio, Emitter identification and mapping for ESM systems, Ultra wide band-width RWR systems are in the scope of the present invention.

1-12. (canceled)

13. A method of identifying a spectrum and extracting features thereof for RF signals in an ultra-wide bandwidth; said method comprising the steps of
a. obtaining said RF signal to be analyzed;
b. high-pass filtering said obtained signal;
c. digitizing said high filtered signal;
d. analyzing said digitized signal;
wherein said method further comprises a step of spectrum compressing (SC) further comprising splitting said high pass filtered signal into two channels; Phase true-time delay modulating (shifting) said signal within one of said channels.

14. The method according to claims 13, wherein said step of digitizing said high filtered signal comprises digitizing an original high filtered signal, a compressed signal and/or a modulated signal.

15. The method according to claims 13, comprising a step of mixing said original and modulated signals.

16. The method according to claim 13, wherein said step of Phase true-time delay modulating comprises a linear modulation with sub-wavelength increments causes the Doppler frequency shift
$${f}_{d} = \frac{v}{c} \cdot {F}_{c} ,$$
where v is the velocity of the linear range modulation defined by digitally controlled switching circuit, c is the speed of light, f_{d} is the Doppler shift and F_{c} is the carrier frequency.

17. The method according to claim 13, wherein said step of SC comprises linearly mapping high-frequency spectrum within low frequency spectrum.

18. The converter according to claims 17 configured for at least one application selected from the group consisting of;
a. Ultra wide band-width real-time spectrum;
b. Spectrum sensing and management for cognitive radio;
c. Emitter identification and mapping for ESM systems; and
d. Ultra wide band-width RWR systems.

19. The method according to claim 13, wherein said step of digital signal processing comprises fusing spectral information derived from under-sampled measurement of the original frequency and the Doppler shift between original and modulated frequencies enabling calculation of ambiguity-free frequency measurement with Khz scale frequency resolution.

20. A linear-analog-to information converter of an RF signal: said converter comprising:
a. a linear spectrum compression (LSC) unit;
b. two digitizers configured for sampling obtained original and modulated signals;
c. a digital signal processing unit;
wherein said LSC unit further comprises a splitter configured to split a high pass filtered signal to two channels, phase true-time delay line disposed in one of said channels.

21. The converter according to claim 20, wherein said digital signal processing unit comprises Fast Fourier Transform for the processing said digital signals, followed by an algorithmic processing for the cross-detection and association of original and modulated frequencies and the extraction of accurate spectral and temporal signal features.

22. A digital analog-to information converter of an RF signal: said converter comprising:
a. two digitizers configured for sampling obtained signal at two specifically tuned sampling rates;
b. a digital signal processing unit;
wherein said digital signal processing unit is configured for digital Doppler generator processing characterized by predetermined sampling rates, a decimation procedure, Fast Fourier Transformation and a predetermined normalization of the frequency spectrum.

23. The digital analog-to information converter according to claim 22, wherein a relation between the sampling rates at said digitizers is given by:
$${f}_{2} = {f}_{1} \cdot {( 1 + K )}^{- 1} = {f}_{1} \cdot \frac{c}{c + v}$$
where v is the desired Doppler velocity, c is the speed of light, K is the compression ratio, and f₁, f₂ are the sampling rates.

24. The digital analog-to information converter according to claim 22, wherein said digital signal processing unit is configured for decimation of Y₁ to equal length as Y₂, Fast Fourier Transform for each separate digitized channel (F(Y₁) and F(Y₂)), and normalization of the frequency spectrum of Y₂ by the following relation: F(Y₂)*(1+K).

25. The converter according to claims 22, configured for at least one application selected from the group consisting of;
e. Ultra wide band-width real-time spectrum;
f. Spectrum sensing and management for cognitive radio;
g. Emitter identification and mapping for ESM systems; and
h. Ultra wide band-width RWR systems.
